(19) United States
(12) Patent Application Publication
(10) Pub. No.: US 2023/0262906 A1
(43) Pub. Date: Aug. 17, 2023

(54) SUBSTRATE, CHIP, CIRCUIT PACKAGE AND FABRICATION PROCESS

(71) Applicant: Alibaba (China) Co., Ltd., Hangzhou (CN)

(72) Inventor: Hui LIU, Dublin, CA (US)

(21) Appl. No.: 17/670,394

(22) Filed: Feb. 11, 2022

(51) Int. Cl. H05K 3/42; H05K 1/02; H05K 1/05

(52) U.S. Cl. CPC H05K 3/429; H05K 1/0298; H05K 1/05; H05K 2201/0959; H05K 2201/09981; H05K 2201/10007

(57) ABSTRACT

A substrate, a chip, a circuit package and a process of fabricating a substrate are presented. The substrate is provided between an integrated circuit and a printed circuit board, and comprises a core insulating and a buildup insulating layer. The first plated through hole is operable to provide ground through from the printed circuit board to the integrated circuit. The second plated through hole is operable to provide electrical communication carrying signals or power between the integrated circuit and the printed circuit board through the buildup insulating layers. The first plated through hole is formed in tubular shape defined an outer wall and an inner wall, and the second plated through hole is formed in the inner wall and is insulated with the first plated through hole.

### BACKGROUND

Plated through holes (PTHs) through the various layers of the substrate provide electrical communication between different layers to improve effective electrical circuit occupancy.

Plated through holes are provide for ground, signal transmission and power supply. Generally speaking, crosstalk among signal PTH would be a major signal integrity problem, especially for high performance DDR (Double Data Rate SDRAM) interface and PCIe (Peripheral Component Interconnect express) signals. Minimizing mutual-inductance, and hence the crosstalk, is needed to achieve the next generation DDR performance and PCIe performance.

Conventional PTH requires one PTH for signal/power and one PTH for ground (or shared ground PTH). Physically, separate signal/power PTH and ground PTH would take a lot of routing space and electrically, it may create high mutual-inductance. The consequence is high crosstalk among those signals.

### BRIEF SUMMARY OF THE INVENTION

Broadly speaking, the present invention fills these needs by providing a substrate, a chip, a circuit package and a process of fabricating a substrate in order to achieve high performance and high routing density for packages such as CPU/AI chips. It should be appreciated that the present invention can be implemented in numerous ways, including as a method, a system, or a device. Several inventive embodiments of the present invention are described below.

In accordance with aspects of the invention, a multi-conductor through hole structure can include one or more through holes disposed in a first insulating region. A first conductor region can be disposed about a wall of the one or more through holes. A second conductor region can be disposed in the one or more through holes. A second insulating region can be disposed between an inside all of the first conductor region and a wall of the second conductor region.

In accordance with one aspect of the invention, a substrate is provided. The substrate is provided between an integrated circuit and a printed circuit board, and comprises a core insulating layer and a buildup insulating layer. The core insulating layer comprises first and second plated through holes extending through the core insulating layer. The buildup insulating layer is disposed over first and second surfaces of the core insulating layer. The first plated through hole is operable to provide ground through from the printed circuit board to the integrated circuit. The second plated through hole is operable to provide electrical communication carrying signals or power between the integrated circuit and the printed circuit board through the buildup insulating layers. The first plated through hole is formed in tubular, cylindrical, conical, rectangular or similar shape defined by an outer wall and an inner wall, and the second plated through hole is formed in the inner wall of the first plated through hole and is insulated from the first plated through hole.

Alternatively, the first plated through hole and the second plated through hole are arranged coaxially.

Alternatively, an insulative material is disposed between the second plated through hole and the inner wall of the first plated through hole.

Alternatively, the insulative material is arranged coaxial between the first plated through hole and the second plated through hole.

Alternatively, the insulative material and the first plated through hole are both formed to be cylindrical.

Alternatively, a first conductive material layer can be disposed between the buildup insulating layer and the core insulating layer and electrically coupled to first plated through holes.

Alternatively, the substrate further comprises a second conductive material layer disposed between the buildup insulating layer and the core insulating layer, for providing electrical communication carrying signals or power. The first plated through hole on the first or second surface of the core insulating layer can be discontinuous at a gap area, and the second conductive material layer disposed between the buildup insulating layer and the core insulating layer can be electrically coupled to the second plated through hole through the gap area.

Alternatively, the substrate further comprises a third conductive material layer disposed on the surface of the buildup insulating layer opposite to the core insulating layer. A third plated through hole extends through the buildup insulating layer and has electrical communication with the third conductive material layer, for providing electrical communication carrying signals or power.

In accordance with another aspect of the invention, a chip is provided. The chip comprises an integrated circuit, and the substrate according to anyone of last aspect. The substrate disposed between the integrated circuit and a printed circuit board.

In accordance with another aspect of the invention, a circuit package is provided. The circuit package comprises the chip according to the last aspect, and a printed circuit board. The chip is disposed on the printed circuit board.

In accordance with aspects of the invention, a method of fabricating a multi-conductor through hole structure can include forming a through hole through a first insulating layer. A first conductor layer can be formed in the first though hole. A second insulating layer can be formed in the first conductor layer, and a second conductor layer can be formed in the second insulating layer.

In accordance with another aspect of the invention, a process of fabricating substrate is provided. The process comprises: forming a first through hole through a core insulating layer; plating a conductive material in the first through hole; forming a second through hole through the core insulating layer in the conductive material, with the portion between the first and the second through hole as a first plated through hole for providing ground; forming an insulative material in the first plated through hole; forming, through the core insulating layer in the insulative material, a second plated through hole for providing electrical communication carrying signals or power.

In accordance with another aspect of the invention, a process of fabricating substrate is provided. The process comprises: forming a first through hole through a core insulating layer, and forming a pre-made piece by forming in an insulative material a second plated through hole for providing electrical communication carrying signals or power; plating a conductive material in the first through hole; forming a second through hole through the core insulating layer in the conductive material, with the portion between the first and the second through hole as a first plated through hole for providing ground; fitting the pre-made piece into the second through hole through the core insulating layer.

In accordance with another aspect of the invention, a process of fabricating substrate is provided. The process comprises: forming a first through hole through a core insulating layer, and forming a pre-made piece by: forming in an insulative material a second plated through hole for providing electrical communication carrying signals or power, and plating a conductive material on the outer wall of an insulative material; fitting the pre-made piece into the first through hole through the core insulating layer, to form a first plated through hole defined by the outer wall of an insulative material and the first through hole for providing ground.

Other aspects and advantages of the invention will become apparent from the following detailed description, taken in conjunction with the accompanying drawings, illustrating by way of example the principles of the invention.

### BRIEF DESCRIPTION OF THE DRAWINGS

The invention, together with further advantages thereof, may best be understood by reference to the following description taken in conjunction with the accompanying drawings.

FIG. 1 illustrates a cross section view of a circuit package including a substrate in accordance with one example.

FIG. 2 illustrates a cross section view of a substrate in accordance with one embodiment of the present invention.

FIG. 3 illustrates a top view of one example of plated through holes on the surface of a core insulating layer of FIG. 2.

FIG. 4 illustrates a top view of another example plated through holes on the surface of a core insulating layer of FIG. 2.

FIG. 5 illustrates a top view of another example plated through holes on the surface of a core insulating layer of FIG. 2.

FIG. 6 illustrates a cross section view of a chip including a substrate in accordance with another embodiment of the present invention.

FIG. 7 illustrates a process of fabricating a multi-conductor through hole structure in accordance with an embodiment of the present invention.

FIG. 8 illustrates a process of fabricating a multi-conductor through hole structure in accordance with another embodiment of the present invention.

FIG. 9 illustrates a process of fabricating a multi-conductor through hole structure in accordance with another embodiment of the present invention.

FIG. 10 illustrates a process of fabricating a multi-conductor through hole structure in accordance with another embodiment of the present invention.

FIG. 11 illustrates a process of fabricating a multi-conductor through hole structure in accordance with another embodiment of the present invention.

### DETAILED DESCRIPTION OF THE INVENTION

The following embodiments describe an apparatus and method for minimizing differential loss and cross-talk in a multilayer substrate. It will be obvious, however, to one skilled in the art, that the present invention may be practiced without some or all of these specific details. In other instances, well known process operations have not been described in detail in order not to unnecessarily obscure the present invention.

FIG. 1 illustrates a cross section view of a circuit package including a substrate in accordance with one example. The circuit package 10 includes an integrated circuit (IC) 103, a substrate 100 for the integrated circuit 103, a printed circuit board (PCB) 104. Integrated circuit 103 is a semiconductor chip, such as a microprocessor, field programmable gate arrays (FPGAs), application specific integrated circuits (ASICs), flash memories, and complex programmable logic devices (CPLDs). The substrate 100 can provide communication between the integrated circuit 103 and the printed circuit board 104 through an IC bump grid array and an array of solder balls. In one embodiment, a direct current (DC) power supply 130 and a ground 110 are provided to the integrated circuit 103 through the PCB 104.

Referring further to FIG. 1, The substrate 100 comprises core insulating layer 101 and a buildup insulating layer 102. A core insulating layer 101 comprises ground plated through hole 110, signal plated through hole 120 and power plated through hole 130 extending through the core insulating layer 101. A buildup insulating layer 102 is disposed over at least one surface of first and second surfaces of the core insulating layer 101 wherein the first surface is one surface of the core insulating layer 101 that faces upwards in the FIG. 1, and the second surface is the other surface of the core insulating layer 101 that faces downwards in the FIG. 1. Furthermore, ground plated through hole 110 is operable to provide ground through from the printed circuit board 104 to the integrated circuit 103, and signal plated through hole 120 and power plated through hole 130 are operable to provide electrical communication carrying signals and power between the integrated circuit 103 and the printed circuit board 104 through the buildup insulating layers 102.

Specifically, the DC power supply provides through conducting layer 121, 131 supply a voltage to the integrated circuit 103 to activate a device on the integrated circuit 103 through certain power path. The electric flow generated by the activated device on the integrated circuit 103 is grounded through a return path 111.

FIG. 1 illustrates an example where the integrated circuit 103 is in electrical communication with the substrate 100. The embodiment may use an IC bump grid array to provide electrical communication between the integrated circuit 103 and the printed circuit board 104, and the substrate 100 is provided for illustrative purposes, and is not meant to limit the present invention to a particular substrate for providing electrical communication between the substrate 100 and the integrated circuit 103. In another embodiment, a number of bond wires originating from the integrated circuit 103 to the surface of the substrate 100 provides electrical communication between the integrated circuit 103 and the substrate 100.

Physically, the structure of signal plated through hole 120 or power plated through hole 130 and ground plated through hole 110 is taking a lot of routing space and electrically, plated through holes are creating high mutual-inductance and high crosstalk among those signals.

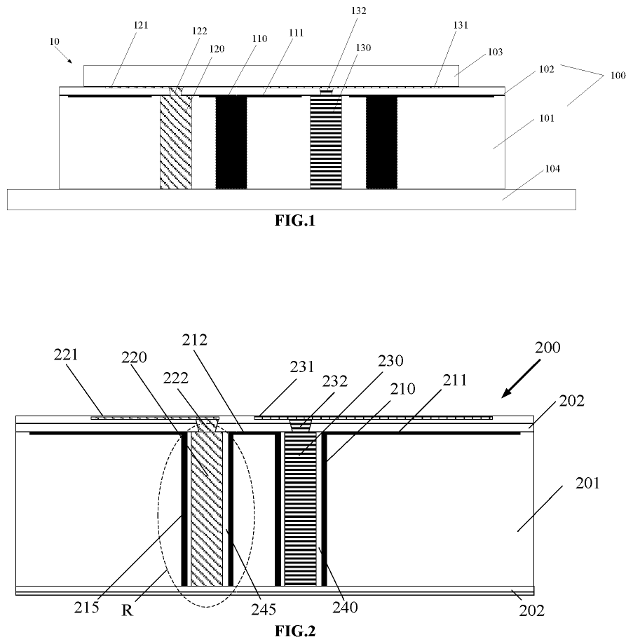

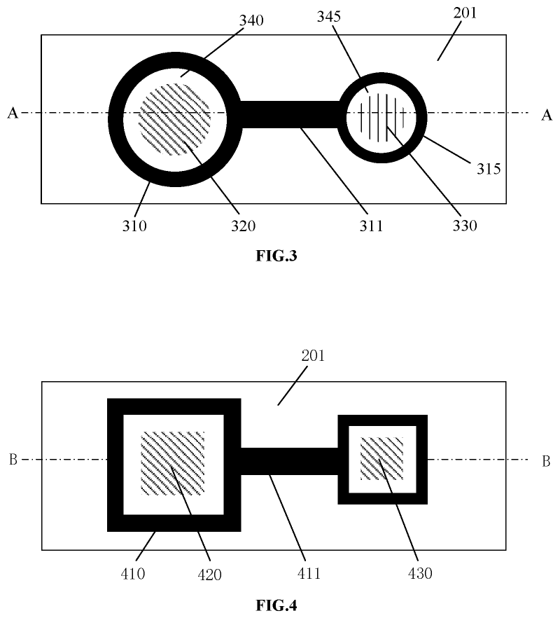

FIG. 2 illustrates a cross section view of a substrate in accordance with another embodiment of the present invention. The substrate can include one or more through holes 210, 215 disposed in a first insulating region 201. A first conductor region 212 can be disposed about a wall of the one or more through holes 210, 215. A second conductor region 220, 230 can be disposed in the one or more through holes 210, 215. A second insulating region 240, 245 can be disposed between an inside wall of the first conductor region 212 and a wall of the second conductor region 220, 230. The first conductor region 212 and second conductor regions 220, 230 can be coaxially arranged. The first conductor region 212 and the second conductor regions 220, 230, can be formed to be cylindrical, rectangular or other similar shape.

In one implementation, a substrate 200 of the embodiment can be provided between an integrated circuit (not shown) and a printed circuit board (not shown). The substrate 200 comprises a core insulating layer 201 and a buildup insulating layer 202. A buildup insulating layer 202 herein may be one or plurality of buildup insulating layers. One or more multi-conductor through hole structures 210-245 can be formed through the core insulating layer 201.

The multi-conductor through hole structures 210-245 can include a through hole 210, 215, a ground plated region 212 disposed in the through hole 210, 215, a power/signal region 220,230 disposed in the through hole 210, 215, and an insulative material region 240, 245 disposed between the ground plated region 212 and the power/signal region 220, 230. The ground plated region 212 and the power/signal region 220, 230 can extend through the core insulating layer 201. A buildup insulating layer 202 can be disposed over first and second surfaces of the core insulating layer 201. The ground plated region 212 can further be disposed on one or more portions of the surfaces of the core insulating layer 201.

Furthermore, the ground plated region 212 is operable to provide a ground through from the printed circuit board to the integrated circuit, and the power/signal region 220,230 is operable to provide electrical communication carrying signals or power between the integrated circuit and the printed circuit board through the buildup insulating layers 202. It should be noted that one or more portions of the ground plated region 212 disposed on the surface of a core insulating layer 201 may be of any shape and may be different from one another.

Furthermore, the ground plated region 212 can have tubular shape defined by an outer wall and an inner wall, wherein the outer wall of the ground plated region 212 is coincident with the wall of the through hole 210, 215. The insulative material region 240, 245 similarly can have a tubular shape defined by an outer wall and an inner wall, wherein the outer wall of the insulative material region 240, 245 is coincident with the inner wall of the ground plated region 212. The power/signal region 220,230 can be disposed inside the inner wall of the insulative material region 240, 245. Therefore, the power/signal region 220, 230 can be disposed within the ground plated region 212, and insulated from each other by the insulative material region 240, 245.

In the embodiment of the present invention, a short distance between the ground plated region 212 and the power/signal region 220, 230 is realized compared to separate plated through hole structures, thus low PDN (Power Distribution Network) impedance is realized to maintain power integrity in the circuit. Furthermore, for high bandwidth chips, especially for DDR interface, the coaxial structure of the ground plater region 212 and power/signal region 220, 230 significantly reduces the area needed for ground and signal/power routing.

For the purpose of clarity, only two types of plated through hole structures are shown for ground and power/signal, respectively. In addition, the relative thicknesses of the various layers are not drawn to scale. The buildup insulating layer 202 consists of insulating layers with conductive layers in between. In one embodiment, the substrate 200 consists of four conducting layers and three insulating layers as buildup insulating layers 202 and one core insulating layer 201. Between the first insulating layer and the second insulating layer as buildup insulating layers 202 is a conductive layer. A core insulating layer 201 may be used to separate the buildup insulating layer 202 on one side of the core insulating layer from the buildup insulating layer 202 on the other side. In one embodiment, the thickness for the core insulating layer 201 is of certain value such 800 μm or so. For each buildup insulating layer 202 is of certain value such as 35 μm or so. The exemplary thicknesses of the core insulating layer 201 and the buildup layer 202 are for illustrative purposes and are not meant to be limiting.

The through hole 210 and the power/signal region 220,230 are arranged coaxially within a certain tolerance. In other word, extremely low self-induct among the PDN path is created. As self-inductance cross plated through holes is a major contribution of the total PDN self-inductance, coaxial PTH structure significantly decreases the self-inductance.

In some embodiments, the insulative material region 240, 245, having an inner wall and outer wall, is provided around the conductive material which forms in the power/signal region 220, 230, the inner wall of the insulative material being in contact with the conductive material of the power/signal region 220, 230, and the outer wall of the insulative material regions 240, 245 being in contact with the conductive material from the ground plated region 212. In other words, the conductive material which forms in the power/signal region 220, 230 has an outer wall that contacts the insulative material region 240, 245, and the conductive material from the ground plated region 212 has an inner wall that contacts the insulative material region 240, 245. Furthermore, the core insulating layer 201 has a wall that contacts the conductive material of the ground plated region 212.

For the fabrication process of the multi-conductor through hole structures 210-245, a number of steps can be taken as follows: forming a first through hole 210, 215 through a core insulating layer 201, plating a conductive material 212 in the first through hole, forming an insulative material 240, 245 within the walls of the conductive plating material 212, forming a second through hole through the insulative material 240, 245, and forming a conductive material 220, 230 in the second through hole.

In another fabrication process of the multi-conductor through hole structures 210-245, a number of steps can be taken as follows: forming a first through hole 210, 215 through a core insulating layer 201, plating a conductive material 212 in the first through hole, forming a layer or film of insulative material 240, 245 on the inner walls of the conductive plating material 212, forming a conductive material 220, 230 filling the space within the inner walls of the layers of insulative material 240, 245.

Alternatively, the multi-conductor through hole structure 210-245 may otherwise be formed by fitting, into a first through hole 210, 215 of the core insulating layer 201, a pre-made piece which has a conductive coating over an insulative material 240, 245 surrounding a conductive core 220, 230. When the pre-made piece is being processed into a tubular shape, the surface (that is, the outer wall of the insulative material 240 or the outer wall of the coating) of the pre-made piece is not necessarily formed coaxially with the conductive core 220, 230, in this way, a certain process tolerance is considered, enhancing the efficiency of the process. Similarly, multi-conductor through hole structure 210-245 may otherwise be formed by fitting, into a first plated through hole of the core insulating layer, a pre-made piece which has a conductive coating over an insulative material 245.

The second conductive material 220, 230 can be disposed in a tubular through hole 210, 215. Specifically, the tubular through hole 210 is formed or defined by an inner wall belonging to the core insulating layer. The insulative material 240, 245 can be disposed between the outer wall of second conductive material 220, 230 and the inner wall of the first conductive material 212 disposed on the wall of the through hole 210, 215. In one example, the insulative material 240, 245 is arranged coaxial with the first conductive material and the second conductive material 220, 230. In one example, the insulative material 240, 245 and the through hole 210, 215 are both formed to be cylindrical.

In some embodiments, in the fabrication process of the second conductive material 220, 230, a number of steps can be taken by: forming an insulative material 240, 245 in the first plated through hole 210, 212, and forming, through the insulative material 240, 245, a second conductive material 220, 230 for providing electrical communication carrying signals or power.

Alternatively, the second conductive material 220,230 may otherwise be formed by forming a through hole in the pre-made piece which may consist of an insulative material 240, 245 or may include a conductive coating 212 over the outer wall of insulative piece. In the case of the pre-made piece consisting of an insulative material 240, 245, the pre-made piece is prepared for fitting into the through hole 210, 215 as above. In the case of the pre-made piece overcoated by a conductive material 212, the pre-made piece is prepared for fitting into the through hole 210, 215 as above. When the pre-made piece is being processed into a tubular shape, the inner wall the second conductive material 220, 230 is not necessarily formed coaxially with the surface of the pre-made piece in either case, in this way, a certain process tolerance is considered, enhancing the efficiency of the process.

Furthermore, a first conductive material layer 211 is disposed between the buildup insulating layer and the core insulating layer, for providing electrical communication of conductive materials between adjacent first plated through holes. a second conductive material layer 221, 231 is disposed between the buildup insulating layer and the core insulating layer, for providing electrical communication carrying signals or power. A third plated through hole 222, 232 extends through the buildup insulating layer and has electrical communication with the third conductive material layer, for providing electrical communication carrying signals or power.

Some embodiments of multi-conductor through hole structures on the surface of a core insulating layer will be described with reference to FIGS. 3-5. Patterns of the multi-conductor through hole structures on the surface of a core insulating layer 201 may be of various shape depending on layout of wirings on the surface.

Referring to FIG. 3, in one embodiment, the ground plated region 310, 315 (colored in black) on the left-hand side and right-hand side form in a circular ring shape (corresponding to a tubular through hole) on the surface of the core insulating layer 201. Inside the respective ring shape is round shape (shadowed) of the power/signal region 320, 330 (cylindrical through hole) on the surface, the round shadowed portion on the left-hand side may be for signal transmitted, while the round shadowed portion on the right-hand side may be for power supply. Furthermore, between the ground plated region 310, 315 and power/signal regions 320, 330 is the insulative material region 340, 345 which forms in a ring shape on the surface of the core insulating layer 201.

Referring further to FIG. 4, the embodiment is different with that of FIG. 3 in that rectangular rings of the ground plated regions 410, 415 on the surface are illustrated, and inside of the rectangular rings are the rectangular section of the power/signal regions 420,430.

Furthermore, in either of embodiment of FIG. 3 or FIG. 4, a first conductive material layer 311, 411 is shown on the surface for providing electrical communication of conductive materials between adjacent ground plated regions 310, 315 and 410, 415, in order to provide a more stable potential of ground. Furthermore, wirings carrying signals or power may be different depending on the pattern of the plated through holes on the surface. In one example, a third conductive material layer (not shown) may be disposed on the surface of the buildup insulating layer opposite to the core insulating layer. Additionally plated through holes can extend through the buildup insulating layer to the third conductive material layer, for providing electrical communication carrying signals or power.

Referring further to FIG. 5, a second conductive material layer 521,531 may be disposed on the surface of the core insulating layer 201 (between the buildup insulating layer and the core insulating layer), for providing electrical communication carrying signals or power. The inner wall 513 and the outer wall 512 of the ground plated region on the first or second surface of the core insulating layer 201 are discontinuous at a gap area 540, and the second conductive material layer 521, 531 is in electrical communication with the power/signal region 520, 530 through the gap area 540, enabling the core insulating layer 201 to provide dense ground wirings.

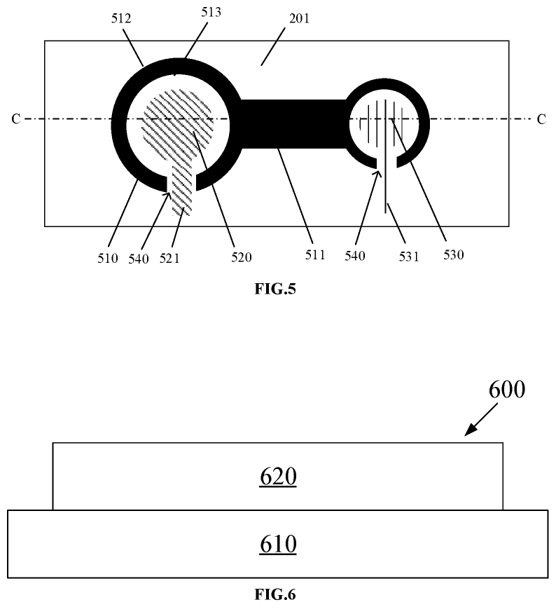

Several embodiments of FIGS. 6-9 will be described as follows.

FIG. 6 illustrates a cross section view of a chip including a substrate in accordance with another embodiment of the present invention. A chip 600 according to FIG. 6 comprises an integrated circuit 620 and the substrate 610 according to any embodiment as above. The substrate disposed between the integrated circuit 620 and a printed circuit board.

In another embodiment of the present invention, A circuit package comprises the chip according to the embodiment of FIG. 6, a printed circuit board. The chip is disposed on the printed circuit board. It should be noted that other than the core insulating layer, the embodiment of FIG. 6 applies to structure according to FIG. 1. the substrate of FIG. 6 applies to structure according to FIG. 2

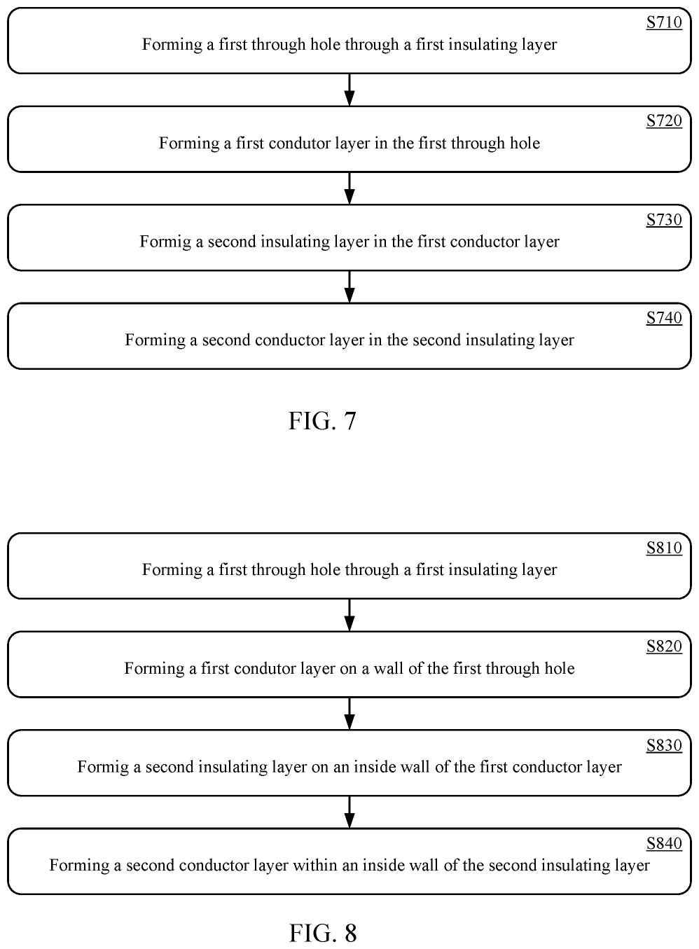

FIG. 7 illustrates a process of fabricating a multi-conductor through hole structure in accordance with an embodiment of the present invention. The process of fabricating the multi-conductor through hole structure can include:

S710: Forming a first through hole through a first insulating layer.

S720: Forming a first conductor layer in the first through hole.

S730: Forming a second a second insulating layer in the first conductor layer.

S740: Forming a second insulative layer in the first conductor layer.

In the embodiment of the present invention, the second insulative layer can have an inner wall and outer wall, with the inner wall of the second insulative layer being in contact with the second conductor layer and the outer wall of the second insulative layer being in contact with the first conductive layer. Accordingly, a short distance between the first conductor layer and second conductor layer is realized as compared to the structure of two separate plated through holes, thus low PDN (Power Distribution Network) impedance is realized to maintain power integrity in the circuit. Furthermore, for high bandwidth chips, especially for DDR interface, the coaxial structure of first plated through hole and the second conductive material significantly reduces the area needed for ground and signal/power routing.

FIG. 8 illustrates a process of fabricating a multi-conductor through hole structure in accordance with another embodiment of the present invention. The process of fabricating the multi-conductor through hole structure can include:

S810: Forming a first through hole through a first insulating layer.

S820: Forming a first conductor layer on a wall of the first through hole.

S830: Forming a second insulating layer on an inside wall of the first conductor layer.

S840 Forming a second conductor layer within an inside wall of the second insulating layer.

In the embodiment of the present invention, the second insulative layer can have an inner wall and outer wall, with the inner wall of the second insulative layer being in contact with the second conductor layer and the outer wall of the second insulative layer being in contact with the first conductive layer. Accordingly, a short distance between the first conductor layer and second conductor layer is realized as compared to the structure of two separate plated through holes, thus low PDN (Power Distribution Network) impedance is realized to maintain power integrity in the circuit. Furthermore, for high bandwidth chips, especially for DDR interface, the coaxial structure of first conductor layer and the second conductor layer significantly reduces the area needed for ground and signal/power routing.

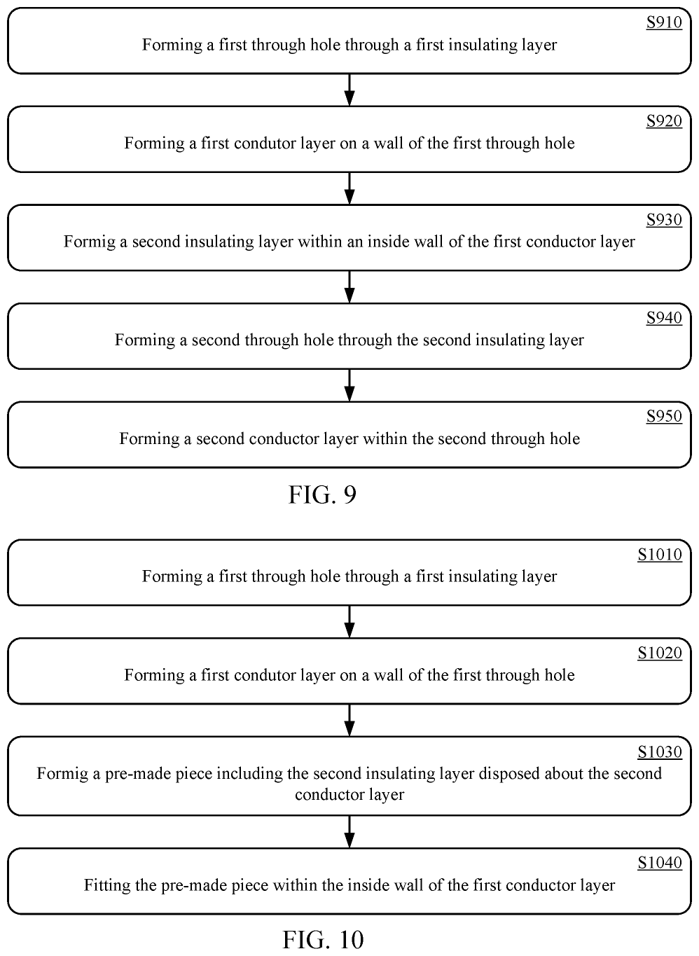

FIG. 9 illustrates a process of fabricating a multi-conductor through hole structure in accordance with another embodiment of the present invention. The process of fabricating the multi-conductor through hole structure can include:

S910: Forming a first through hole through a first insulating layer.

S920: Forming a first conductor layer on a wall of the first through hole.

S930: Forming a second insulating layer within an inside wall of the first conductor layer.

S940: Forming a second through hole through the second insulating layer.

S940 Forming a second conductor layer within the second through hole.

In the embodiment of the present invention, the second insulative layer can have an inner wall and outer wall, with the inner wall of the second insulative layer being in contact with the second conductor layer and the outer wall of the second insulative layer being in contact with the first conductive layer. Accordingly, a short distance between the first conductor layer and second conductor layer is realized as compared to the structure of two separate plated through holes, thus low PDN (Power Distribution Network) impedance is realized to maintain power integrity in the circuit. Furthermore, for high bandwidth chips, especially for DDR interface, the coaxial structure of first conductor layer and the second conductor layer significantly reduces the area needed for ground and signal/power routing.

FIG. 10 illustrates a process of fabricating a multi-conductor through hole structure in accordance with another embodiment of the present invention. The process of fabricating the multi-conductor through hole structure can include:

S1010: Forming a first through hole through a first insulating layer.

S1020: Forming a first conductor layer on the wall of the first through hole.

S1030: Forming a pre-made piece including a second insulating layer disposed about a second conductor layer.

S1040: Fitting the pre-made piece within the inside wall of the first conductor layer.

Accordingly, a short distance between the first conductor layer and the second conductor layer is realized as compared to the structure of two separate plated through holes, thus low PDN (Power Distribution Network) impedance is realized to maintain power integrity in the circuit. Furthermore, for high bandwidth chips, especially for DDR interface the coaxial structure of the first conductive layer and second conductive layer significantly reduces the area needed for ground and signal/power routing.

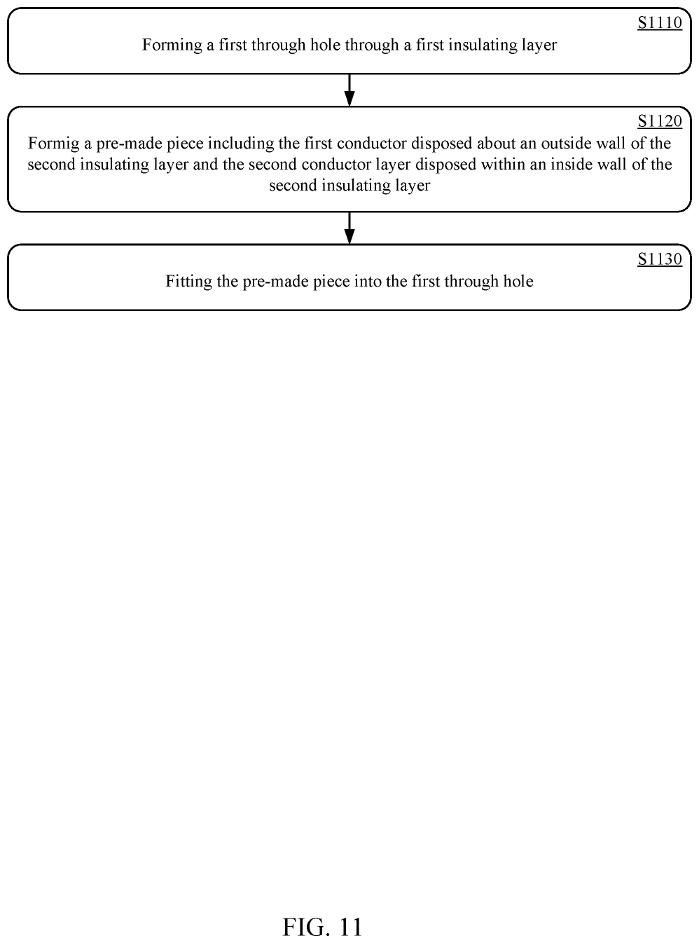

FIG. 11 illustrates a process of fabricating a multi-conductor through hole structure in accordance with another embodiment of the present invention. The process of fabricating the multi-conductor through hole structure can include:

S1110: Forming a first through hole through a first insulating layer.

S1120: forming a pre-made piece including a first conductor disposed about an outside wall of a second insulating layer and a second conductor layer disposed within an inside wall of the second insulating layer.

S1130: Fitting the pre-made piece into the first through hole.

Accordingly, a short distance between the first and second conductive material is realized compared to separate structures of two plated through holes, thus low PDN (Power Distribution Network) impedance is realized to maintain power integrity in the circuit. Furthermore, for high bandwidth chips, especially for DDR interface, the coaxial structure of the first and second conductor layers significantly reduces the area needed for signal/power routing.

It should be noted that the embodiment of FIG. 7-11 applies to structure according to FIG. 2.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims.

1. A substrate provided between an integrated circuit and a printed circuit board, comprising:
a core insulating layer comprising first and second plated through holes extending through the core insulating layer;
a buildup insulating layer disposed over first and second surfaces of the core insulating layer;
wherein the first plated through hole is operable to provide ground through from the printed circuit board to the integrated circuit,
wherein the second plated through hole is operable to provide electrical communication carrying signals or power between the integrated circuit and the printed circuit board through the buildup insulating layers,
wherein the first plated through hole is formed in tubular shape defined by an outer wall and an inner wall, and the second plated through hole is formed in the inner wall and is insulated from the first plated through hole.

2. The substrate of claim 1, wherein the first plated through hole and the second plated through hole are arranged coaxially.

3. The substrate of claim 1, wherein an insulative material is disposed between the second plated through hole and the inner wall of the first plated through hole.

4. The substrate of claim 3, wherein the insulative material is arranged coaxial with the first plated through hole and the second plated through hole.

5. The substrate of claim 1, further comprising:
a first conductive material layer disposed between the buildup insulating layer and the core insulating layer and electrically coupled to first plated through hole.

6. The substrate of claim 5, further comprising:
a second conductive material layer disposed between the buildup insulating layer and the core insulating layer, for providing electrical communication carrying signals or power,
wherein the first plated through hole one the first or second surface of the core insulating layer is discontinuous at a gap area, and a second conductive material layer disposed between the buildup insulating layer and the core insulating layer is electrical coupled to the second plated through hole through the gap area.

7. The substrate of claim 5, further comprising:
a third conductive material layer disposed on the surface of the buildup insulating layer opposite to the core insulating layer,
wherein a third plated through hole extends through the buildup insulating layer and has electrical communication with the third conductive material layer, for providing electrical communication carrying signals or power.

8. A multi-conductor through hole structure comprising:
one or more through holes disposed in a first insulating region;
a first conductor region disposed about a wall of the one or more through holes;
a second conductor region disposed in the one or more through holes; and
a second insulating region disposed between an inside wall of the first conductor region and a wall of the second conductor region.

9. The multi-conductor through hole structure of claim 8, wherein the first conductor region and the second conductor region are arranged coaxially.

10. The multi-conductor through hole structure of claim 8, wherein the first conductor region and the second conductor region are formed to be cylindrical.

11. The multi-conductor through hole structure of claim 8, wherein the first conductor region and the second conductor region are formed to be rectangular.

12. A substrate comprising:
the multi-conductor through hole structure according to claim 8;
a buildup insulating layer disposed over a surface of the core insulating layer;
the first conductor region further disposed on one or more portions of the surface of the core insulating layer between the buildup insulating layer and the core insulating layer;
one or more third conductor layers disposed on the buildup insulating layer opposite the core insulating layer; and
one or more fourth conductor regions disposed through the buildup insulating layer between respective ones of one or more third conductor layers and respective one of the second conductor regions.

13. The substrate of claim 12, wherein the first conductor region further disposed on one or more portions of the surface of the core insulating layer is discontinuous at a gap area, and the second conductive region is in electrical coupled with the XXX through the gap area

14. A circuit package comprising:
a substrate including one or more multi-conductor through hole structures according to claim 8; and
an integrated circuit coupled to the substrate, wherein ground, power and signal subcircuits of the integrated circuit are electrically coupled to respective ground plated regions and power/signal regions of respective ones of the one or more multi-conductor through hole structures of the substrate.

15. The circuit package of claim 14, further comprising:
a printed circuit board coupled to the substrate opposite the integrated circuit.

16. A method of fabricating a multi-conductor through hole structure comprising:
forming a first through hole through a first insulating layer;
forming a first conductor layer in the first through hole;
forming a second insulating layer in the first conductor layer; and
forming a second conductor layer in the second insulating layer.

17. The method according to claim 16, wherein:
forming the first conductor layer comprises forming the first conductor layer on a wall of the first through hole; and
forming the second insulating layer and the second conductor layer includes;
forming a second insulating layer on an inside wall of the first conductor layer; and
forming the second conductor layer within an inside wall of the second insulating layer.

18. The method according to claim 16, wherein:
forming the first conductor layer comprises forming the first conductor layer on a wall of the first through hole;
forming the second insulating layer and the second conductor layer includes;
forming a second insulating layer within an inside wall of the first conductor layer;
forming a second through hole through the second insulating layer; and
forming the second conductor layer within the second through hole.

19. The method according to claim 16, wherein:
forming the first conductor layer comprises forming the first conductor layer on a wall of the first through hole; and
forming the second insulating layer and the second conductor layer includes;
forming a pre-made piece including the second insulating layer disposed about the second conductor layer;
fitting the pre-made piece into the inside wall of the first conductor layer.

20. The method according to claim 16, wherein:
forming the second insulating layer and the second conductor layer includes;
forming a pre-made piece including the first conductor layer disposed about an outside wall of the second insulating layer and the second conductor layer disposed about an inside wall of the second insulating layer;
fitting the pre-made piece into the first through hole.
